(19) United States
(12) Patent Application Publication
(10) Pub. No.: US 2013/0263916 A1
(43) Pub. Date: Oct. 10, 2013

(54) ALL SPRAY SEE-THROUGH ORGANIC SOLAR ARRAY WITH ENCAPSULATION

(71) Applicants: Jason Eric Lewis, Lutz, FL (US); Xiaomei Jane Jiang, Tampa, FL (US)

(72) Inventors: Jason Eric Lewis, Lutz, FL (US); Xiaomei Jane Jiang, Tampa, FL (US)

(73) Assignee: UNIVERSITY OF SOUTH FLORIDA, Tampa, FL (US)

(21) Appl. No.: 13/854,602

(22) Filed: Apr. 1, 2013

Related U.S. Application Data
(63) Continuation of application No. PCT/US2011/054290, filed on Sep. 30, 2011.
(60) Provisional application No. 61/388,347, filed on Sep. 30, 2010.

(51) Int. Cl. H01L 31/0224; H01L 51/44; H01L 31/05

(52) U.S. Cl. CPC H01L 31/022475; H01L 31/0504; H01L 51/44
USPC 136/251; 136/256; 438/64

(57) ABSTRACT

An inverted organic solar photovoltaic cell is described that may be fabricated onto rigid or flexible substrates using spray-on technology to apply the various layers of the cell. Indium tin oxide with a thin layer of cesium carbonate functions as the cathode for the novel inverted cells. An active layer of poly-3(hexylthiophene) and [6,6]-phenyl C61-butyric acid methylester having a thickness around 200 nm to 600 nm facilitates a high level of light transmittal through the cell. A modified PEDOT:PSS, made by doping a conductive polymer with dimethylsulfoxide (DMSO), functions as the anode. A method of forming the inverted organic solar photovoltaic cell is also described using gas-propelled spraying to achieve thin layers. After the layers are formed, the cell is sealed using a vacuum and temperature-based annealing and encapsulation with UV-cure epoxy.

### CROSS-REFERENCE TO RELATED APPLICATIONS

This application is a continuation of prior filed International Application, Serial Number PCT/US2011/054290 filed Sep. 30, 2011, which claims priority to U.S. Provisional Patent Application No. 61/388,347, entitled “All Spray See-through Organic Solar Array with Encapsulation”, filed on Sep. 30, 2010, the contents of which are herein incorporated by reference.

### FIELD OF INVENTION

This invention relates to organic solar cells. Specifically, the invention is an inverted organic solar cell that is prepared using spray-on methods.

### BACKGROUND OF THE INVENTION

In recent years, energy consumption has drastically increased, due in part to increased industrial development throughout the world. The increased energy consumption has strained natural resources, such as fossil fuels, as well as global capacity to handle the byproducts of consuming these resources. Moreover, future demands for energy are expected in greatly increase, as populations increase and developing nations demand more energy. These factors necessitate the development of new and clean energy sources that are economical, efficient, and have minimal impact on the global environment.

Photovoltaic cells have been used since the 1970s as an alternative to traditional energy sources. Because photovoltaic cells use existing energy from sunlight, the environmental impact from photovoltaic energy generation is significantly less than traditional energy generation. Most of commercialized photovoltaic cells are inorganic solar cells using single crystal silicon, polycrystal silicon or amorphous silicon. However, these inorganic silicon-based photovoltaic cells are produced in complicated processes and at high costs, limiting the use of photovoltaic cells. These silicon wafer-based cells are brittle, opaque substances that limit their use, such as on window technology where transparency is a key issue. Further, installation is an issue since these solar modules are heavy and brittle. In addition, installation locations, such as rooftops, are limited compared to the window area in normal buildings, and even less in skyscrapers. To solve such drawbacks, photovoltaics cell using organic materials have been actively researched.

The photovoltaic process in OPV first starts from the absorption of light mainly by the polymer, followed by the formation of excitons. The exciton then migrates to and dissociates at the interface of donor (polymer)/acceptor (fullerene). Separated electrons and holes travel to opposite electrodes via hopping, and are collected at the electrodes, resulting in an open circuit voltage (V_{oc}). Upon connection of electrodes, a photocurrent (short circuit current, I_{sc}) is created.

Organic photovoltaic cells based on π-conjugated polymers have been intensively studied following the discovery of fast charge transfer between polymer and carbon C₆₀. Conventional organic photovoltaic devices use transparent substrates, such as an indium oxide like indium tin oxide (ITO) or IZO, as an anode and aluminum or other metal as a cathode. A photoactive material including an electron donor material and an electron acceptor material is sandwiched between the anode and the cathode. The donor material in conventional devices is poly-3-hexylthiophene (P3HT), which is a conjugated polymer. The conventional acceptor material is (6,6)-phenyl C₆₁ butyric acid methylester (PCBM), which is a fullerene derivative. Both the ITO and aluminum contacts use sputtering and thermal vapor deposition, both of which are expensive, high vacuum, technologies. In these photovoltaic cells, light is typically incident on a side of the substrate requiring a transparent substrate and a transparent electrode. However, this limits the materials that may be selected for the substrate and electrode. Further, a minimum thickness of 30 to 500 nm is needed to increasing conductivity. Moreover, the organic photoelectric conversion layer is sensitive to oxygen and moisture, which reduce the power conversion efficiency and the life cycle of the organic solar cell. Development of organic photovoltaic cells, has achieved a conversion efficiency of 3.6% (P. Peumans and S. R. Forrest, Appl. Phys. Lett. 79, 126 (2001)).

These polymeric OPV holds promise for potential cost-effective photovoltaics since it is solution processable. Large area OPVs have been demonstrated using printing (Krebs and Norman, Using light-induced thermocleavage in a roll-to-roll process for polymer solar cells, ACS Appl. Mater. Interfaces 2 (2010) 877-887; Krebs, et al., A roll-to-roll process to flexible polymer solar cells: model studies, manufacture and operational stability studies, J. Mater. Chem. 19 (2009) 5442-5451; Krebs, et al., Large area plastic solar cell modules, Mater. Sci. Eng. B 138 (2007) 106-111; Steim, et al., Flexible polymer Photovoltaic modules with incorporated organic bypass diodes to address module shading effects, Sol. Energy Mater. Sol. Cells 93 (2009) 1963-1967; Blankenburg, et al., Reel to reel wet coating as an efficient up-scaling technique for the production of bulk heterojunction polymer solar cells, Sol. Energy Mater. Sol. Cells 93 (2009) 476-483), spin-coating and laser scribing (Niggemann, et al., Organic solar cell modules for specific applications—from energy autonomous systems to large area photovoltaics, Thin Solid Films 516 (2008) 7181-7187; Tipnis, et al., Large-area organic photovoltaic module—fabrication and performance, Sol. Energy Mater. Sol. Cells 93 (2009) 442-446; Lungenschmied, et al., Flexible, long-lived, large-area, organic solar cells, Sol. Energy Mater. Sol. Cells 91 (2007) 379-384), and roller painting (Jung and Jo, Annealing-free high efficiency and large area polymer solar cells fabricated by a roller painting process, Adv. Func. Mater. 20 (2010) 2355-2363). ITO, a transparent conductor, is commonly used as hole collecting electrode (anode) in OPV, and a normal geometry OPV starts from ITO anode, with the electron accepting electrode (cathode) usually a low work function metal such as aluminum or calcium, being added via thermal evaporation process.

In addition, to improve efficiency of the organic thin film solar cell, photoactive layers were developed using a low-molecular weight organic material, with the layers stacked and functions separated by layer. (P. Peumans, V. Bulovic and S. R. Forrest, Appl. Phys. Lett. 76, 2650 (2000)). Alternatively, the photoactive layers were stacked with a metal layer of about 0.5 to 5 nm interposed to double the open end voltage (V_{oc}). (A. Yakimov and S. R. Forrest, Appl. Phys. Lett. 80, 1667 (2002)). As described above, stacking of photoactive layer is one of the most effective techniques for improving efficiency of the organic thin film solar cell. However, stacking photoactive layers can cause layers to melt due to solvent formation from the different layers. Stacking also limits the transparency of the photovoltaic. Interposing a metal layer between the photoactive layers can prevent solvent from one photoactive layer from penetrating into another photoactive layer and preventing damage to the other photoactive layer. However, the metal layer also reduces light transmittance, affecting power conversion efficiency of the photovoltaic cell.

However, in order for solar cells to be compatible with windows, issues with the transparency of the photovoltaic must first be addressed. Another challenge is to reduce cost for large scale manufacturing in order for organic solar cells to be commercially viable, a much lower manufacturing cost to compensate for the lower efficiency than current photovoltaic products. For example, a solution-based all-spray device, which was opaque, showed a PCE as high as 0.42% (Lim, et al., Spray-deposited poly(3,4-ethylenedioxythiophene):poly(styrenesulfonate) top electrode for organic solar cells, Appl. Phys. Lett. 93 (2008) 193301-193304). Large-scale manufacturing techniques, such as printing, have lowered the cost of manufacture, but still involve the use of metal in certain way, and therefore affect the transparency of the photovoltaic cell.

Therefore, what is needed is a new method of manufacturing organic photovoltaic cells without the use of metal, to allow for novel photovoltaic cells with enhanced transparency. The art at the time the present invention was made did not describe how to attain these goals, of manufacturing less expensive and less complex devices, having enhanced transparency.

### SUMMARY OF THE INVENTION

Conventional technology based on spin-coating and using metal as cathode contact greatly limits transparency of solar cells and posts difficulty for large scale manufacturing. The present invention provides a new spray technology that solves these two problems simultaneously using thin film organic layers applied via a layer-by-layer spray technique. The inverted organic solar photovoltaic cell may be fabricated onto most any desired substrates, both rigid and flexible. Exemplary substrates include cloth, glass, and plastic. For example, the substrate may be a low alkaline earth boro-aluminosilicate glass.

A patterned ITO layer is added to one face of the substrate, structured as a series of contacts oriented in a first direction on the substrate. A patterned interfacial buffer layer of Cs₂CO₃ overlays the ITO layer, and aids in the ITO's function as the cathode for the inverted cell. The Cs₂CO₃ layer may be overlaid at any thickness known in the art to be useful for forming an ITO cathode. A thickness of between 5\acute{Å} to 15 \acute{Å} has been found especially useful. An active layer of poly-3(hexylthiophene) and [6,6]-phenyl C61-butyric acid methylester overlays the layer of Cs₂CO₃. While the thickness of the active layer may vary, testing has shown the active layer is especially useful at about 200 nm thick to about 500 nm thick, and more specifically at a thickness of about 200 to about 300 nm. An anodic layer comprising poly(3,4)ethylenedioxythiophene:poly-styrenesulfonate and 5 vol. % of dimethylsulfoxide overlays the active layer, and is about 100 nm to about 1 μm thick. In specific variations of the invention, the thickness of the anodic layer is about 100 nm to about 600 nm, or more specifically about 100 nm. The inverted cell is sealed using a UV-cured epoxy encapsulant or silver paint. The completed inverted organic solar photovoltaic cell has in certain embodiments, an active layer thickness of 200 nm and an anodic layer the thickness of 600 nm.

The inverted organic solar photovoltaic cell may be constructed in an array, such as a series of 50 individual cells having active area of 60 mm². In some variations, the array is oriented as 10 cells disposed in series in one row, and 5 rows in parallel connection.

The method of preparing the inverted organic solar photovoltaic cell is also provided. A substrate was obtained comprising a transparent piezoelectric material coated with indium tin oxide. In some variations, a positive photo resist was spin-coated at about 4500 rpm, and then soft baked at 90° C. to pattern the indium tin oxide. The baked positive photo resist was then exposed to UV irradiation at a constant intensity mode set to about 25 watts, developed, and hard-baked at about 145° C. The excess photoresist was cleaned off excess using acetone and cotton; and then etched with a solution of 20% HCl-7% HNO₃ at 100° C. The inverted organic solar photovoltaic cell was then optionally cleaned using acetone followed by isopropanol, then followed by a UV-ozone clean for at least fifteen minutes. A cathode was formed by spray coating a layer of cesium carbonate on top of the indium tin oxide coating. The cesium carbonate was optionally prepared as known in the art. A useful preparation was made by preparing a solution of 0.2% wt. (2 mg/mL) Cs₂CO₃ in 2-ethoxyethanol, which was stirred for one hour. The solution was then placed into a spray device containing N₂ propellant for application onto the cathode.

Afterwards, an active layer was formed by spray coating a layer of poly-3(hexylthiophene) and [6,6]-phenyl C61-butyric acid methylester disposed on the layer of Cs₂CO₃, wherein the active layer was about 200 nm thick to about 500 nm thick. The active layer was optionally prepared using methods available to one of skill in the art. A useful preparation was formed by mixing a solution of poly(3-hexylthiophene) in dichlorobenzene at 20 mg/mL for 24 hours at 60° C. and a solution of 6,6-phenyl C61 butyric acid methyl ester in dichlorobenzene at 20 mg/mL for 24 hours at 60° C., in separate containers. The solution of poly(3-hexylthiophene) and solution of 6,6-phenyl C61 butyric acid methyl ester were then combined at a ratio of 1:1 and stirred for 24 hours at 60° C., followed by placing the solution into a spray device containing N₂ propellant for application to the inverted organic solar photovoltaic cell. In some variations of the inverted organic solar photovoltaic cell preparation, multiple light layers were sprayed first, typically as applications of 600-900 μm. A final thick continuous coat was then applied to complete the active layer coating.

The active layer was then overlaid with an anodic layer by spraying poly(3,4)ethylenedioxythiophene:poly-styrenesulfonate doped with 5 vol. % of dimethylsulfoxide on the active layer, wherein the anodic layer is about 100 nm to about 1 μm thick. The inverted organic solar photovoltaic cell was then encapsulated by applying a UV-cured epoxy encapsulant or silver paint to the edges of the cell. The anode was optionally prepared using methods available to one of skill in the art. However, a useful preparation was formed by filtering a solution of poly(3,4)ethylenedioxythiophene and poly(styrenesulfonate) through a 0.45 μm filter and mixing the filtered solution with a solution of dimethylsulfoxide to form a final concentration of dimethylsulfoxide of 5 vol %, followed by stirring the solution of poly(3,4)ethylenedioxythiophene-poly(styrenesulfonate)-dimethylsulfoxide at room temperature. The solution was then sonified for one hour and placed into a spray device containing N₂ propellant for application.

The layers of the inverted organic solar photovoltaic cell were then optionally annealed together by subjecting the organic inverted solar photovoltaic cell to a vacuum of 10⁻⁶ Torr, followed by annealing the organic inverted solar photovoltaic cell at 120° C. Additionally, inverted organic solar photovoltaic cell may be subjected to a two-step annealing, including subjecting the substrate to a high vacuum at 10⁻⁶ Torr for a second hour and annealing the organic inverted solar photovoltaic cell at 160° C.

Once the layers of the inverted organic solar photovoltaic cell are prepared, which includes the application and optional annealing, the inverted organic solar photovoltaic cell is encapsulated by applying the silver paint to at least one contact on the substrate and allowing the paint to dry. An encapsulation substrate was then notched and cleaned using acetone and isopropanol. The encapsulation substrate may be any transparent material known in the art, such as the material used to form the substrate. An optional UV-ozone cleaning was then performed. The inverted organic solar photovoltaic cell and encapsulation substrate were placed into a glovebox with a UV-cure epoxy, the UV-cure epoxy to the edge of the encapsulation glass, and the inverted organic solar photovoltaic cell substrate and placing it onto the encapsulation glass. The cell was then exposed to UV-ozone.

The resulting inverted organic solar photovoltaic cell uses all solution-processable organic solar layers with transparent contacts, allowing for improved transmittal of light trough the inverted organic solar photovoltaic cell. Current power conversion efficiency of −1.3% is achieved for a single cell with an active area of four millimeters squared (4 mm²), and provides an open circuit voltage of 0.39 volts and a short circuit current of 0.46 mA.

### BRIEF DESCRIPTION OF THE DRAWINGS

For a fuller understanding of the invention, reference should be made to the following detailed description, taken in connection with the accompanying drawings, in which:

FIG. 1 is a diagram that depicts the modified PEDOT:PSS as it is sprayed onto the substrate through a stainless steel shadow mask with an airbrush. Nitrogen is used as the carrier gas at a pressure of 20 psi.

FIG. 2 is a diagram showing a perspective view of the novel inverted OPV cells containing sprayed-on layers.

FIG. 3 is a graph comparing the voltage versus current plots of the novel inverted OPV and a control device fabricated by means of conventional bottom-up structure.

FIG. 4 is a diagram showing the novel organic photovoltaic cell as it receives photons having energy hv.

FIG. 5 is a graph showing voltage versus current and shows how the Cs₃CO₃ layer affects the performance of the inverted cells when there is no Cs₃CO₃ layer and with the Cs₃CO₃ layer but at different spin rates.

FIG. 6 is a graph showing the transmission spectra of PEDOT:PSS with 5% DMSO at different spray thickness indicated, the range of thickness from 500 nm to 1 μm, and transmittance at 550 nm 60˜60%.

FIG. 7 is a graph showing a comparison of the transmittance between ITO and the spray-on anode of m-PEDOT (modified PEDOT:PSS) with different thicknesses.

FIG. 8 is a graph showing a comparison of the sheet resistance between ITO and the spray-on anode of m-PEDOT (modified PEDOT:PSS) with different thicknesses.

FIG. 9 is a graph showing the transmission spectra of an active layer (P3HT:PCBM) of 200 nm (black line with filled square), and with a m-PEDOT:PSS layer of 600 nm (grey line with filled circle).

FIG. 10 is a graph showing the voltage versus current, indicating how different m-PEDOT layer compositions affect the performance of the inverted photovoltaic cell.

FIG. 11 is a graph showing the I-V characteristics of three test cells measured with AM 1.5 solar illumination under different annealing conditions; 1-step annealing at either 120° C. (light grey circle), or 160° C. (black filled square) for 10 min; 2-step annealing at 120° C. for 10 min, followed by high vacuum for 1 h and annealing at 160° C. for 10 min (medium grey triangle).

FIG. 12 is a graph showing the IPCE of the three test cells of FIG. 5a under tungsten lamp illumination. Different annealing conditions were 1-step annealing at either 120° C. (light grey circle), or 160° C. (black filled square) for 10 min; 2-step annealing at 120° C. for 10 min, followed by high vacuum for 1 h and annealing at 160° C. for 10 min (medium grey triangle).

FIG. 13 is a diagram showing the cross sectional view of the device architecture of an inverted solar array showing series connection

FIG. 14 is a graph showing the I-V characteristics of 4 inverted spray-on solar arrays measured with AM 1.5 solar illumination under various annealing conditions: 1-step annealing at 120° C. (dashed line), or 160° C. (thin grey line), and 2-step annealing (black filled square). These 3 arrays use m-PEDOT 750 as the anode. The 4th array (thick black line) used m-PEDOT 500 as the anode and was annealed at 160° C.

FIG. 15 is a graph showing the I-V characteristics of an inverted solar array under continuous AM 1.5 solar illumination. The first measurement (dashed black line) was done right after the array was fabricated and encapsulated. The inset shows the time dependence of I-V characteristics of a spray-on test cell (without encapsulation).

### DETAILED DESCRIPTION OF THE PREFERRED EMBODIMENT

There are two different approaches in inverted geometry. One approach is completely ITO-free, using a wrap-through method by Zimmermann et. al. (Zimmermann, et al., ITO-free wrap through organic solar cells—a module concept for cost-efficient reel-to-reel production, Sol. Energy Mater. Sol. Cells 91 (2007) 374-378), or the use of a Kapton foil and an Aluminum/Chromium bi-layer system as electron contact (Manceau, et al., ITO-free flexible polymer solar cells: from small model devices to roll-to-roll processed large modules, Org. Electron. 12 (2011) 566-574), and the formation of a bottom electrode comprising silver nanoparticles on a 130 μm thick polyethyleneternaphthalate (PEN) substrate by Krebs et. al. (Krebs, All solution roll-to-roll processed polymer solar cells free from indium-tin-oxide and vacuum coating steps, Org. Electron. 10 (2009) 761-768). Another approach is to add an electron transport layer onto ITO to make it function as a cathode. Inverted geometry OPVs in which the device was first built from modified ITO as cathode have been studied both in single cells (Huang, et al., A Semi-transparent plastic solar cell fabricated by a lamination process, Adv. Mater. 20 (2008) 415-419; Yu, et al., Efficient inverted solar cells using TiO2 nanotube arrays, Nanotechnology 19 (2008) 255202-255207; Li, et al., Efficient inverted polymer solar cells, Appl. Phys. Lett. 88 (2006) 253503-253506; Zou, et al., Metal grid/conducting polymer hybrid transparent electrode for inverted polymer solar cells, Appl. Phys. Lett. 96 (2010) 203301-203304; Waldauf, et al., High efficient inverted organic photovoltaics using solution based titanium oxide as electron selective contact, Appl. Phys. Lett. 89 (2006) 233517-233520; Zhou, et al., Inverted and transparent polymer solar cells prepared with vacuum-free processing, Sol. Eng. Sol. Cells 93 (2009) 497-500) and solar modules (Krebs and Norman, Using light-induced thermocleavage in a roll-to-roll process for polymer solar cells, ACS Appl. Mater. Interfaces 2 (2010) 877-887; Krebs, et al., A roll-to-roll process to flexible polymer solar cells: model studies, manufacture and operational stability studies, J. Mater. Chem. 19 (2009) 5442-5451; Krebs, et al., Large area plastic solar cell modules, Mater. Sci. Eng. B 138 (2007) 106-111).

OPV single cell utilizing spray technique has been previously reported (Weickert, et al., Spray-deposited PEDOT:PSS for inverted organic solar cells, Sol. Energy Mater. Sol. Cells 94 (2010) 2371-2374; Kim, et al., Performance optimization of polymer solar cells using electrostatically sprayed photoactive layers, Adv. Funct. Mater. 20 (2010) 3538-3546; Kim, et al., Substrate heated spray-deposition method for high efficient organic solar cell: morphology inspection, Jap. J. Appl. Phys. 49 (2010) 01800-01804). However, all these works involve either the use of high vacuum deposition, and/or spin-coating process. The present invention is the first inverted solar array fabricated by spray. Comparing with conventional technology based on spin-coating and using metal as a cathode contact, which greatly limits transparency of solar cells and posts difficulty for large scale manufacturing, the new spray technology solves these two problems simultaneously. A thin film organic solar array is fabricated employing this layer-by-layer spray technique onto desired substrates (can be rigid as well as flexible). This technology eliminates the need for high vacuum, high temperature, low production rate and high-cost manufacturing associated with current silicon and in-organic thin film photovoltaic products. Furthermore, this technology could be used on any type of substrate including cloth and plastic.

As used herein, “about” means approximately or nearly and in the context of a numerical value or range set forth means±15% of the numerical.

As used herein, “substantially” means largely if not wholly that which is specified but so close that the difference is insignificant.

All masks described herein for spray were custom made by Towne Technologies, Inc.

The incident photon converted electron (IPCE), or the external quantum efficiency (EQE), of the device was measured using 250 W tungsten halogen lamp coupled with a monochromator (Newport Oriel Cornerstone 1/4m).

The photocurrent was detected by a UV enhanced silicon detector connected with a Keithley 2000 multimeter. The transmission spectrum of active layer was performed on the same optical setup.

### Example 1

An indium tin oxide (ITO) with and Corning® low alkaline earth boro-aluminosilicate glass substrate (Delta Technology, Inc.) having a nominal sheet resistance of 4-10 Ω/square was pre-cut 4″×4″, and patterned using a positive photo resist, Shipley 1813, spin coated at 4500 rpm and soft baked on a hotplate for 3 minutes at 90° C. The structure was then exposed to a UV lamp for 1.4 seconds using a constant intensity mode set to 25 watts. The structure was developed for about 2.5 minutes using Shipley MF319, rinsed with water, and hard-baked at 145° C. for 4 minutes. Any excess photoresist was cleaned off with acetone and cotton. The substrate was etched 5-11 minutes with a solution of 20% HCl and 7% HNO3 at 100° C. The structure was removed from etchant and cleaned by hand using acetone followed by isopropanol. The structure was further cleaned using UV-ozone for at least fifteen minutes.

A Cs₂CO₃ interfacial buffer layer was prepared by making a solution of 0.2% wt. (2 mg/mL) Cs₂CO₃ (Aldrich) in 2-ethoxyethanol, and stirring the solution for one hour. Cs₂CO₃ was chosen to reduce ITO work function close to 4.0 eV to be utilized as cathode. The layer was applied to the substrate by spray coat using N2 set to 20 psi from a distance of about 7-10 centimeters. The product was then annealed for 10 minutes at 150° C. in an N2 glovebox (MBraun MOD-01).

The active layer solution was prepared by mixing separate solutions of poly(3-hexylthiophene) (P3HT; Riekie Metals, Inc., Lincoln, Nebr.; average molecular weight of 42 K and regioregularity over 99%) and 6,6-phenyl C61 butyric acid methyl ester (PCBM; C60, Nano-C, Inc., Westwood, Mass.; 99.5% purity) in dichlorobenzene at 20 mg/mL. The two solutions were stirred on a hotplate for 24 hours at 60° C., and then the solutions were mixed together at a 1:1 ratio. The mixture was stirred for an additional 24 hours at 60° C., producing a final solution of 10 mg/mL.

The active coating is prepared by spray coating using N2 set to thirty 30 psi from a distance of about 7-10 centimeters. Multiple light layers were sprayed onto the structure first, at about 600-900 μm per spray. A final thick continuous coat was then applied to complete the active layer coating having a final layer thickness of about 200-300 nm. A cotton cloth with DCB was used to wipe excess from the substrate. The structure was then wiped with a cotton cloth in isopropanol. The substrate was then dried in an antechamber under vacuum for at least twelve 12 hours.

A kovar shadow mask was aligned into position and taped onto the substrate. The series connection locations were then wiped using a wooden dowel.

The anodic buffer layer was prepared using a modified poly(3,4)ethylenedioxythiophene (PEDOT) and poly(styrenesulfonate) (PSS) solution (PEDOT:PSS; Baytron 500 and 750; H.C. Starck GmbH., Munich, Germany). The PEDOT:PSS was diluted and filtered out through a 0.45 μm filter. This filtered solution of PEDOT:PSS was mixed with 5 vol % of dimethylsulfoxide and was stirred at room temperature followed by one 1 hour of sonification to form a modified PEDOT:PSS (mPED). The solution PEDOT:PSS, when used alone, has a relatively low conductivity that reduces device performance. The conductivity of PEDOT:PSS was increased by doping it with dimethylsulfoxide.

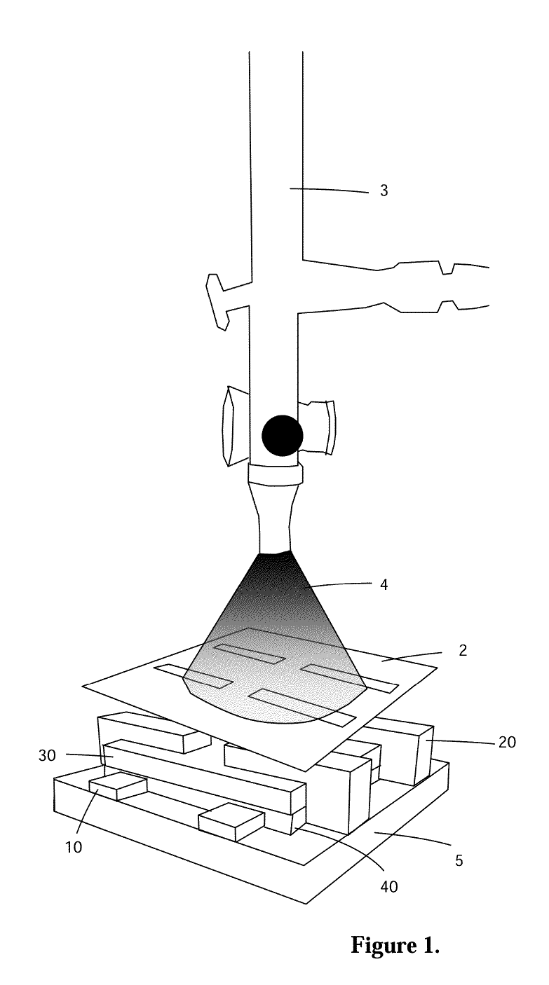

Mask 2 was placed onto the cell containing anode 10, interfacial layer 40 and active layer 30. The mPED coating was prepared by placing the substrate/mask on a hotplate at 90° C. The substrate/mask was spray coated with spray device 3, using nitrogen (N2) as the carrier gas, set to 30 psi from a distance of about seven to ten centimeters 7-10 cm, as seen in FIG. 1. Multiple light layers of spray 4 were applied until the final thickness is reached. The substrate was then removed from the hotplate and the mask is removed. Care was taken to avoid removing the mPED with the mask.

The substrate is then subjected to a high vacuum (10-6 Torr) for 1 hour, which improved the device performance with the sprayed active layer (Lim, et al., Spray-deposited poly(3,4-ethylenedioxythiophene):poly(styrenesulfonate) top electrode for organic solar cells, Appl. Phys. Lett. 93 (2008) 193301-193304). After the vacuum, the device was annealed for 10 minutes at 120° C. The vacuuming and annealing steps were then repeated a second time, at the same conditions. The substrate was finally encapsulated by applying silver paint to the device contacts or a UV-cured encapsulant (EPO-TEK OG142-12; Epoxy Technology, Inc., Billerica, Mass.) and allowing the paint to dry. The encapsulated glass was then notched and cleaned by hand using acetone and isopropanol, followed by at least 15 minutes of UV-ozone cleaning The encapsulated glass was then placed into the glovebox, together with a small quantity of UV-cure epoxy and a paintbrush. The UV-cure epoxy is applied with the paintbrush to the edge of the encapsulation glass. The device was then inverted and placed on top of the encapsulation glass. The device is then exposed to UV-ozone for 15 minutes to cure the encapsulate epoxy.

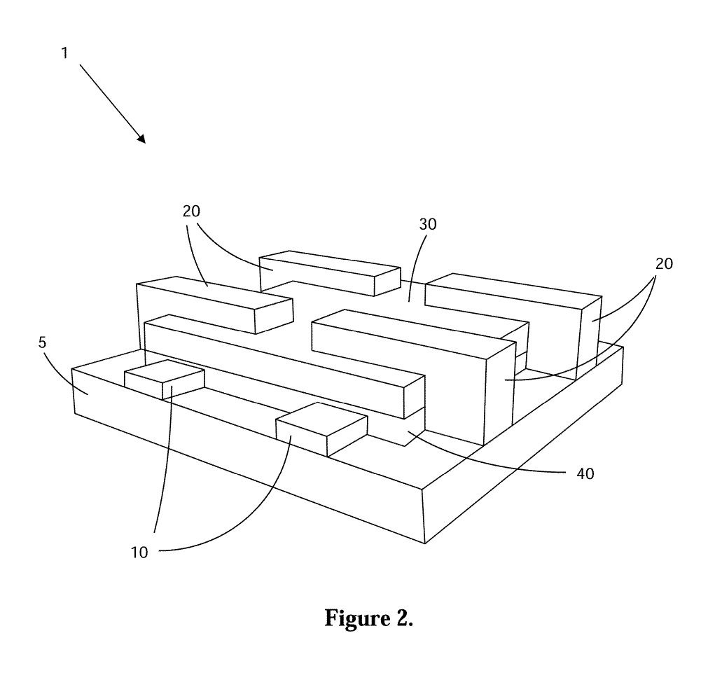

Inverted organic photovoltaic cell 1, seen dissected in FIG. 2, was created using the method described above. Inverted photovoltaic cell 1 was composed of different layers of active materials and terminals (anode and cathode) built onto substrate 5. Anode 10, comprised of ITO in the present example, was sprayed onto substrate 5 forming a ‘¦ ¦’ pattern extending from a first set of edges of substrate 5. Interfacial buffer layer 40 covers anode 10, except for the outermost edges, as seen in FIG. 2. The components of the interfacial buffer layer were chosen to provide a gradient for charges crossing the interface, approximating a conventional p-n junction with organic semiconductors, thereby providing an increased efficiency of heterojunctions. An exemplary interfacial layer is composed of Cs₂CO₃, ZnO, or titanium oxide. Active layer 30 is disposed directly on top of interfacial buffer layer 40, and was prepared using poly(3-hexylthiophene) and 6,6-phenyl C61 butyric acid methyl ester. Anode 20 was disposed on the active layer in a pattern, similar to the cathode, but perpendicular to the cathode. Exemplary anode materials include PEDOT:PSS doped with dimethylsulfoxide. The fully encapsulated 4 μm×4 μm array was found to possess over 30% transparency.

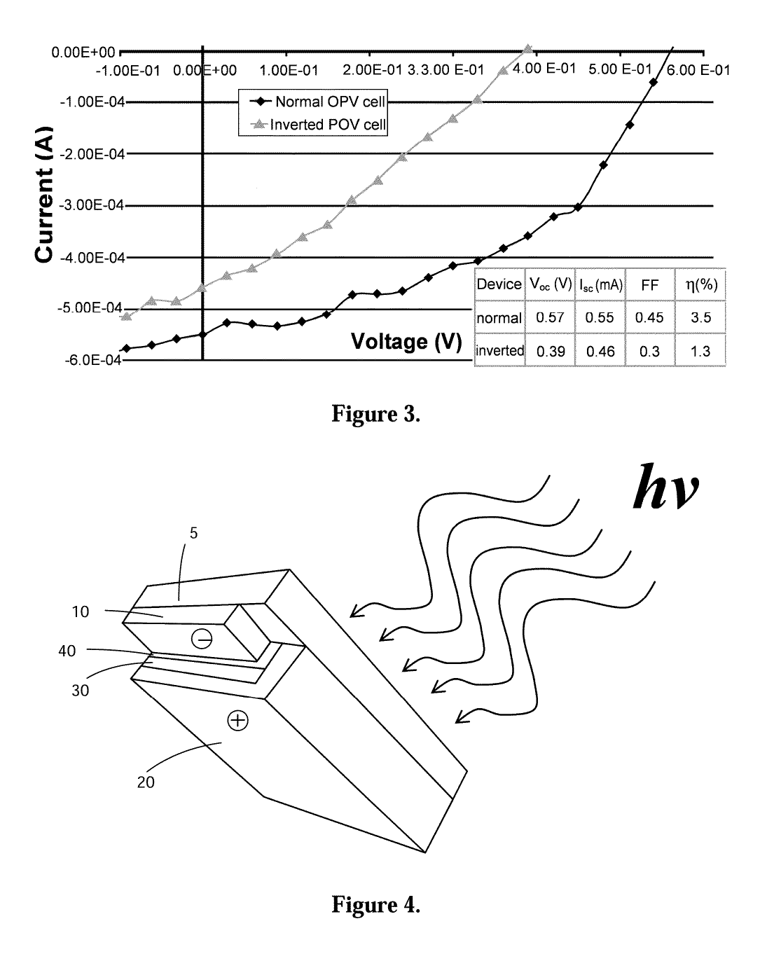

The device was analyzed against a control device fabricated by means of conventional bottom-up structure using a metal cathode by thermo evaporation. At this stage, the novel inverted cell has smaller PCE (1.3%) than that of the control device (3.5%), as seen in FIG. 3.

### Example 2

The photovoltaic cell was tested to determine its photoelectric generation. The organic photovoltaic cell was exposed to photons having energy hv, as seen in FIG. 4. No spectral mismatch with the standard solar spectrum was corrected in the power conversion efficiency (PCE) calculation.

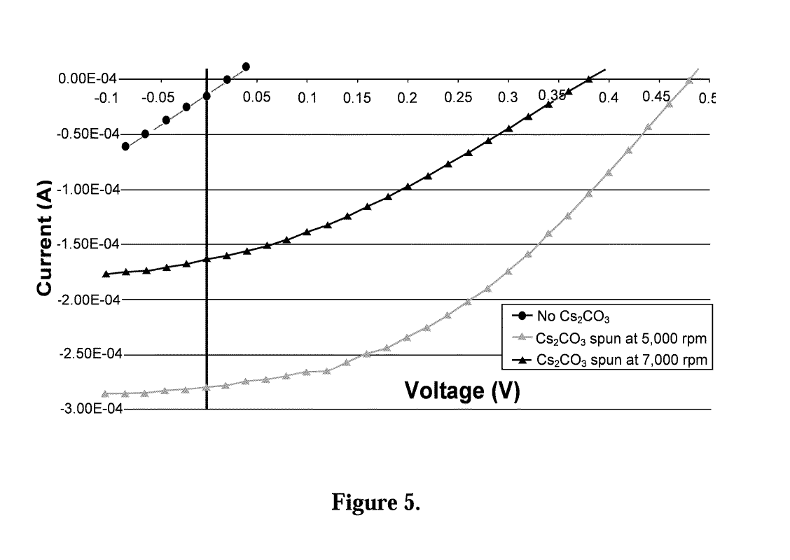

The current-voltage (I-V) characterization of the solar array was performed using a Newport 1.6 KW solar simulator under AM1.5 irradiance of 100 mW/cm2. In order to have a good reference point for the multi-cell array, the inverted single-cell test device, consisted of four identical small cells (4 mm2) on a 1″×1″ substrate, using m-PEDOT 500 as anode. FIG. 5 shows how the Cs₂CO₃ layer affects the performance of the inverted cell. The control cell without Cs₂CO₃ (black circle) performed almost like a resistor and had negligible V_{oc} (0.03 V). The lower performance was due to non-ohmic contact with the cathode, with reduced built-in electric field across the active layer. For a better controlled thickness, Cs₂CO₃ was spin-coated onto the cleaned ITO substrate in these devices. As shown in FIG. 5, the optimal thickness of Cs₂CO₃ layer was achieved at a spin rate of 5000 rpm. At higher rate of 7000 rpm, the device was less efficient owing to the fact of a discontinuous Cs₂CO₃ layer. It was further noted that the optimal thickness is between 10 and 15 Å measured by AFM topography.

ITO normally has a work function of ˜4.9 eV, and is traditionally used as an anode in typical OPV devices. There have been previous reports on tuning the work function of ITO by adding an electron transport layer such as ZnO (Zou, et al., Metal grid/conducting polymer hybrid transparent electrode for inverted polymer solar cells, Appl. Phys. Lett. 96 (2010) 203301-203304), TiO2 (Huang, et al., A Semi-transparent plastic solar cell fabricated by a lamination process, Adv. Mater. 20 (2008) 415-419; Yu, et al., Efficient inverted solar cells using TiO2 nanotube arrays, Nanotechnology 19 (2008) 255202-255207; Li, et al., Efficient inverted polymer solar cells, Appl. Phys. Lett. 88 (2006) 253503-253506), PEO (Zhou, et al., Inverted and transparent polymer solar cells prepared with vacuum-free processing, Sol. Eng. Sol. Cells 93 (2009) 497-500) and Cs₂CO₃ (Huang, et al., A Semi-transparent plastic solar cell fabricated by a lamination process, Adv. Mater. 20 (2008) 415-419; Yu, et al., Efficient inverted solar cells using TiO2 nanotube arrays, Nanotechnology 19 (2008) 255202-255207; Li, et al., Efficient inverted polymer solar cells, Appl. Phys. Lett. 88 (2006) 253503-253506) in inverted OPV single cells. Previous report showed Cs₂CO₃ can lower the ITO work function to as low as 3.3 eV. By spin coating a solution of 2-ethoxyethanol with 0.2% Cs₂CO₃ at 5000 rpm for 60 s, a very thin layer (˜10 Å) of Cs₂CO₃ is formed over the ITO. It was reported that a dipole layer would be created between Cs₂CO₃ and ITO. The dipole moment helped to reduce the work function of ITO, allowing ITO to serve as the cathode.

To estimate of the effective work function of ITO/Cs₂CO₃ cathode, a control device was fabricated with 100 nm aluminum cathode deposited on glass substrate, with the active layer and m-PEDOT layer fabricated the same way as in ITO/Cs₂CO₃ cathode configuration described above. Since aluminum is not transparent, the I-V in both devices were measured by illumination from m-PEDOT side using the same illumination condition for the Aluminum control and the ITO/Cs₂CO₃ cathode device. The V_{oc} of the Aluminum cathode control device was 0.24 V, whereas the V_{oc} of the ITO/Cs₂CO₃ cathode device spun at 7000 rpm was 0.36 V, as seen in FIG. 5. Since aluminum has work function of 4.2 eV, this indicates that, the effective work function of ITO/Cs₂CO₃ is close to 4.1 eV.

### Example 3

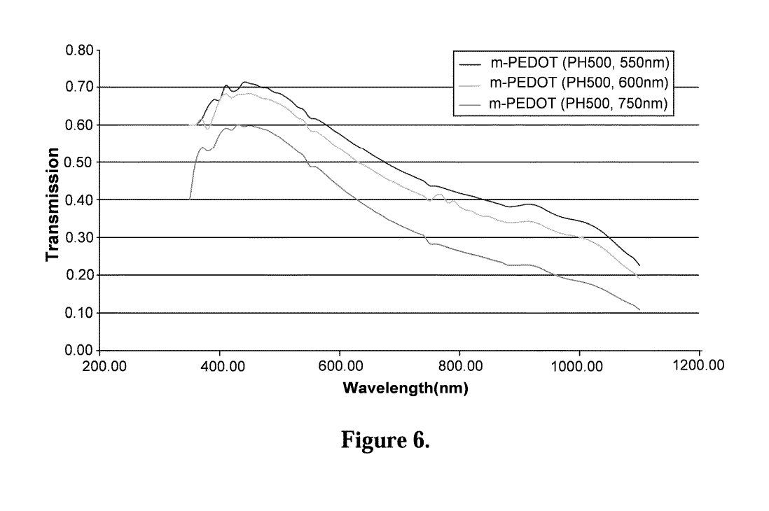

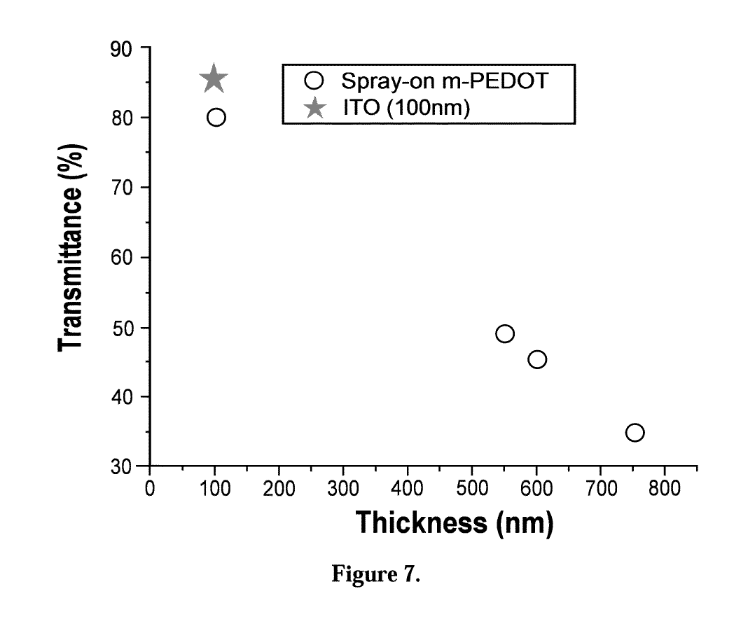

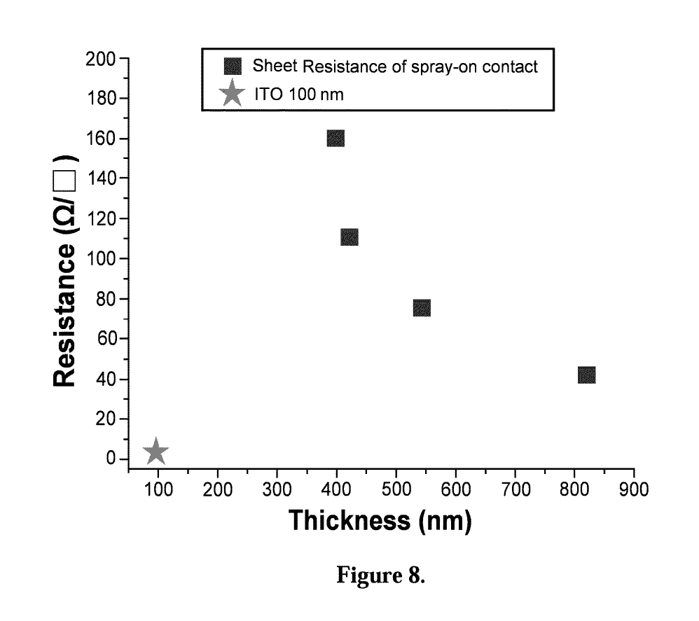

Different compositions of PEDOT:PSS were analyzed to determine optimum active layer constituents. Photovoltaic cells were prepared similarly to the methods described in Example 1, with PH-500 modified 5% DMSO. The transmission spectra of the sprayed-on mPEDOT was measured for different wavelengths, using different thicknesses of active layer, as seen in FIG. 6. FIGS. 7 and 8 show how the thickness of the sprayed-on m-PEDOT layer affects its transmittance and sheet resistance. Transmittance was measured using a 250 W tungsten halogen lamp coupled with a monochromator (Newport Oriel Cornerstone 1/4 m). ITO was chosen as a reference for comparison. At a thickness of about 100 nm, the transmittance of m-PEDOT is about 80%, comparable with ITO, as seen in FIG. 7. The sheet resistance of m-PEDOT was measured using a standard four-point probe measurement (Van Zant, Microchip Fabrication, McGraw-Hill, New York, ISBN 0-07-135636-3, 2000, pp. 431-2; van der Pauw, A method of measuring the resistivity and Hall coefficient on lamellae of arbitrary shape, Philips Tech. Rev. 20 (1958) 220-224). As expected, the resistance decreases as thickness increases, which is consistent with the bulk model, as seen in FIG. 8.

These two parameters (transmittance and sheet resistance) are important to assess the feasibility of m-PEDOT to be used as a replacement contact for the conventional metal contact. The trade-off between transparency and resistance is another important fabrication parameter. The current array was fabricated with thickness of about 600 nm, which has moderate resistance of 70 Ω/square, and transmittance about 50%.

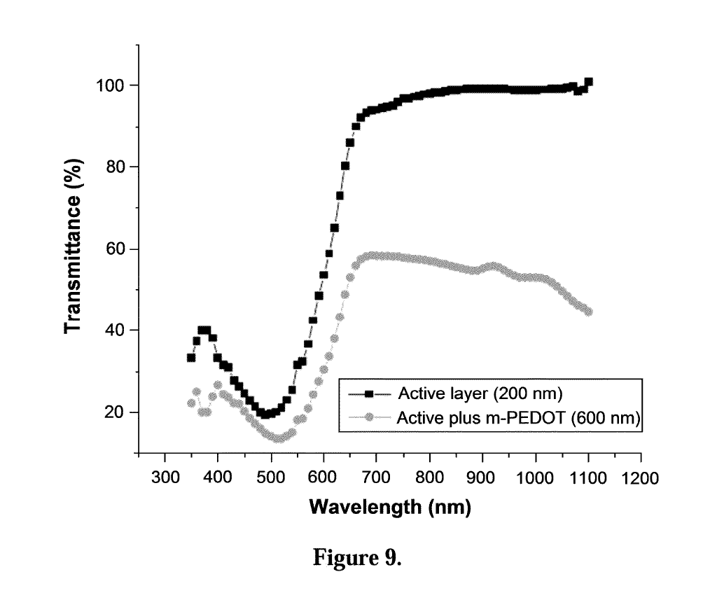

The transmission spectra of the active layer (P3HT:PCBM, 200 nm) and m-PEDOT anode of 600 nm were compared, as seen in FIG. 9. The total transmittance over the spectra range shown decreases from 73% to 31% after spraying on the m-PEDOT anode.

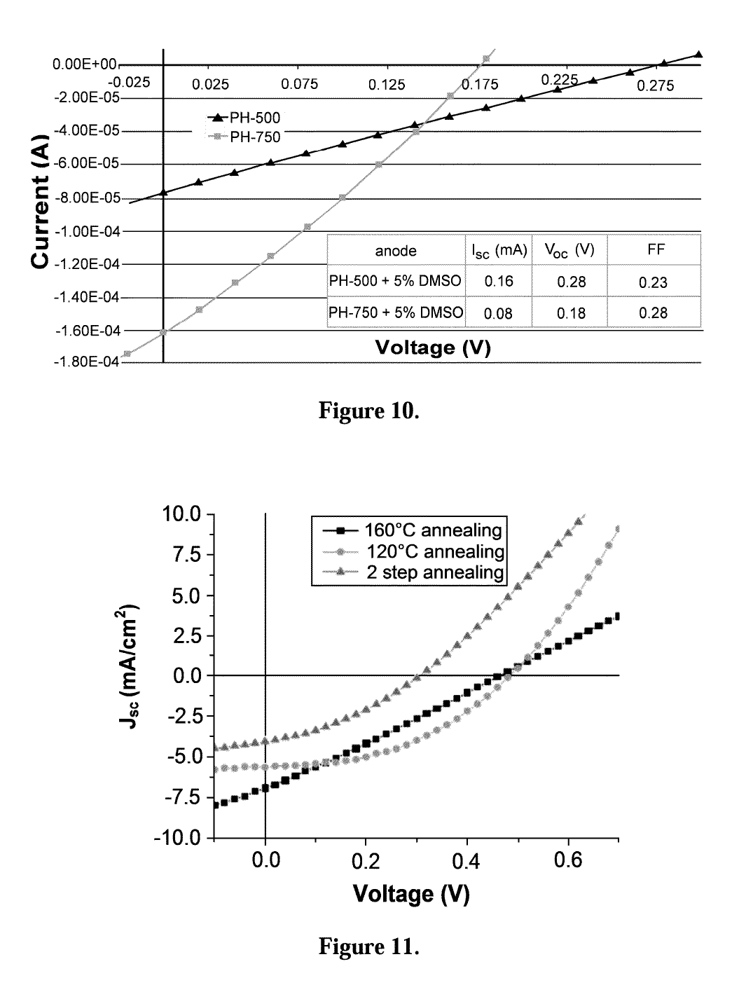

Photovoltaic cells were manufactured using different PEDOT compositions (PH-500 and PH-750) modified with 5% DMSO. The remaining procedures were followed as provided in Example 1, and the performance measured as disclosed above. As seen in FIG. 10, performance for PH-750 showed a strong initial current, which decreased with increasing voltage. Conversely, PH-500 performed poorly at lower voltages, but better than PH-750 at higher voltage.

### Example 4

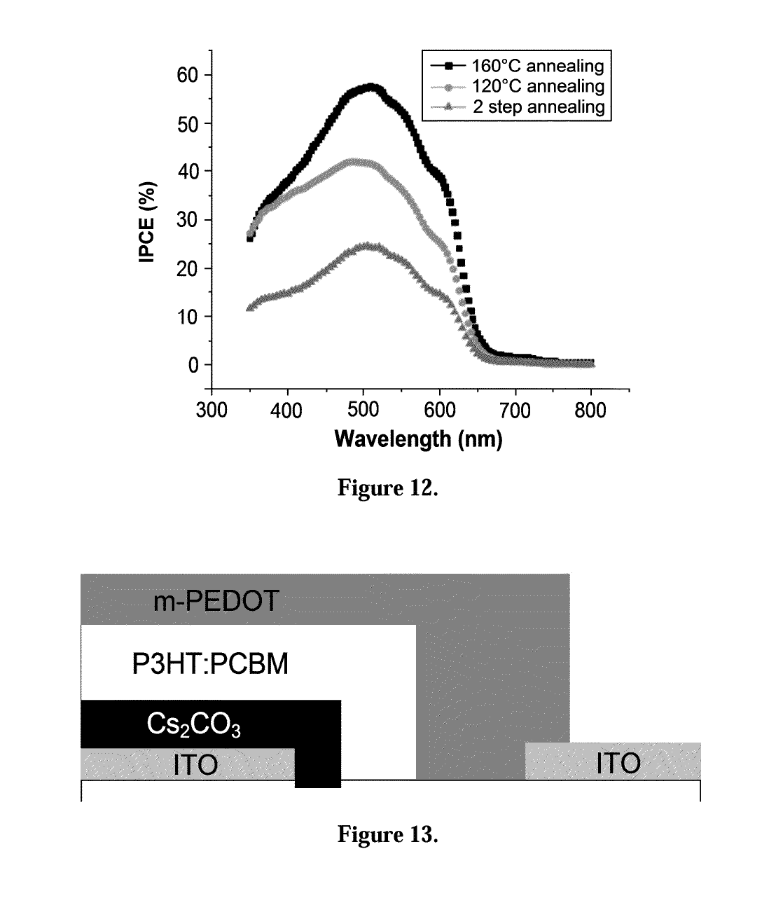

Annealing has shown to be the most important factor to improve organic solar cell performance. Photovoltaic cells were prepared as described above, except with the annealing occurring in one step at 120° C. for 10 min., one step at 160° C. for 10 min, or a two-step annealing at 120° C. for 10 min followed by high vacuum for 1 hour and then 160° C. for 10 min. FIGS. 11 and 12 show the comparison of current-voltage (I-V) and incident photon converted electron (IPCE) or external quantum efficiency (EQE) between three inverted test cells at the different annealing conditions. The rationale behind choosing such annealing conditions was to experiment both annealing temperature and the thermal profile. FIG. 11 shows that 1-step annealing at 120° C. gives the best result in test cell, with V_{oc}=0.48 V, I_{sc}=0.23 mA, FF=0.44, and a power conversion efficiency (PCE) of 1.2% under AM1.5 solar illumination with intensity 100 mW/cm2. The second annealing step at 160° C. worsens the device performance, mainly due to unfavorable change of film morphology, which was confirmed in AFM images, data not shown. The PCE of 1-step annealing at 160° C. was in between 1-step annealing at 120° C. and 2-step annealing, yet the device has the worst FF. Table 1 listed the details of the I-V characteristics of these three test cells.

TABLE 1
Test cell I-V characteristics comparison at various annealing conditions.

| Test cell | | V_{oc} | | η | |
|---|---|---|---|---|---|
| number | I_{sc} (mA) | (V) | FF | (%) | Annealing condition |
| 1 | 0.28 | 0.48 | 0.26 | 0.86 | 160° C., 10 min |
| 2 | 0.23 | 0.48 | 0.44 | 1.2 | 120° C., 10 min |
| 3 | 0.16 | 0.30 | 0.35 | 0.43 | 2-step |

In FIG. 12, IPCE measurement shows 2-step annealing was worse than 1-step annealing, which was consistent with the I-V measurements, not shown. There seems to be some inconsistency between PCE and IPCE for the cells annealed at 160 and 120° C., as the cells annealed at 160° C. have higher IPCE yet lower PCE than that at 120° C. IPCE measurement was done under illumination from the Tungsten lamp, whereas I-V was done under solar simulator, which has a different spectrum than that of the tungsten lamp. Nevertheless, the integration of IPCE should be proportional to Isc. The device made by 1-step annealing at 160° C., though having smaller power conversion efficiency, actually has larger Isc (0.28 mA) than the one at 120° C. (0.23 mA). The ratio between integral of IPCE at 160° C. vs. 120° C. is about 1.3, and the ratio of Isc of the same devices was 1.2. Without being limited to any theory, the slight discrepancy might also come from the fact that the cells behave differently under strong (IV) and weak (IPCE) illuminations. Usually bi-molecular (BM) recombination sets in under high light intensity (solar simulator) (Shaheen, et al., 2.5% efficient organic plastic solar cells, Appl. Phys. Lett. 78 (2001) 841-843), meaning the cell, which has more prominent BM recombination, will perform poorer with high intensity illumination such as that from the solar simulator. It might be that the cell annealed at 160° C. was affected by BM recombination more than the cell annealed at 120° C., due to more traps associated with rougher morphology, data not shown, serving as recombination centers. The same mechanism can also be applied to explain the larger difference in IPCE of device annealed at 160° C. and by 2-step annealing than that of their Isc in FIGS. 11 and 12.

1-step annealing at 120° C. (b) showed improved film roughness and the best phase segregation of P3HT and PCBM, which explains the high device performance using this annealing profile, as seen in FIGS. 11 and 12. Device by 2-step annealing has the smoothest film, however, the phase segregation was much less distinct. This indicates that P3HT chains and PCBM molecules are penetrating through each other more after the second annealing at 160° C., and form much smaller nano-domains, which are favorable for charge transport between the domains (Kline and McGehee, Morphology and charge transport in conjugated polymers, J Macromol. Sci. C: Polym. Rev. 46 (2006) 27-45). However, recombination of photogenerated carriers might be enhanced due to the lack of separate pathways for electron sand holes, and that was why the device after 2-step annealing performed worse than after the 1st annealing at 120° C., seen in FIGS. 11 and 12. 1-step annealing at higher temperature of 160° C. results in the roughest film (even rougher than the as-made device), and the P3HT phase and PCBM phase are hardly distinguishable. This rough film also further affects the interface between active layer and m-PEDOT, resulting in poor FF of the device, seen in FIGS. 11 and 12.

### Example 5

Solar illumination has been demonstrated to improve solar array efficiency up to 250%. Device efficiency of 1.80% was observed with the array under AM1.5 irradiance. Our preliminary data have shown that the performance enhancement under illumination only happens with sprayed devices, not devices made by spin coating. This means that solar cells made with our spray-on technique performs better under sunlight, which is beneficial for solar energy application.

A solar array was prepared by forming 50 individual inverted cells, each with an active area of 60 mm2, and using either m-PEDOT 750 or m-PEDOT 500 as the semitransparent anode. The array was configured with 10 cells in series in one row to increase the voltage, and five rows in parallel connection to increase the current. The neighboring cells were connected using the organic layer configuration, seen in cross section in FIG. 13.

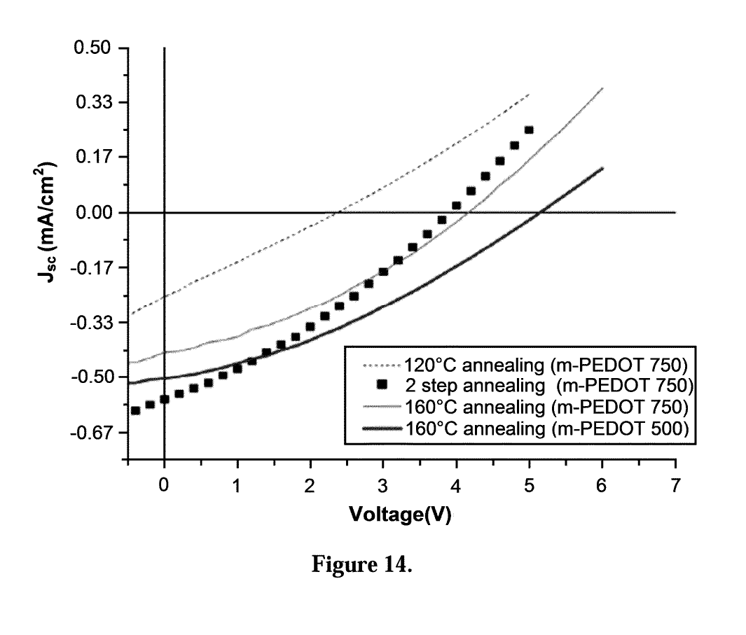

Characteristics of the arrays were tested as described above. The I-V of four arrays prepared using the different annealing conditions described in Example 4, above, were measured with AM1.5 solar illumination, seen in FIG. 14. It is clear that 1-step annealing at low temperature (120° C.) gives the worst result, and 2-step annealing showed improved I-V characteristics (V_{oc}, Jsc, FF and PCE) after the second high temperature annealing at 160° C. 1-step annealing at high temperature (160° C.) gives the best V_{oc}, and 2-step annealing yields the highest Jsc. In terms of anode, m-PEDOT 500 seems to give higher V_{oc} than PEDOT 750, as seen in Table 2. However, there is not much difference of PCE between 2-step annealing and 1-step annealing at 160° C., which is in contrast with the result of the test device, seen in FIGS. 11 and 12. We think the annealing duration is probably too short for the array, since it has much larger area and contains much more materials. Further investigation of interplay between annealing temperature, duration and thermal profile is ongoing to find the optimal device fabrication conditions.

TABLE 2
Array I-V characteristics comparison
at various annealing conditions.

| Array | I_{sc} | V_{oc} | | η | Annealing | |
|---|---|---|---|---|---|---|
| number | (mA) | (V) | FF | (%) | condition | m-PEDOT |
| 1 | 17.0 | 3.9 | 0.30 | 0.68 | 2-step | 750 |
| 2 | 11.5 | 4.0 | 0.39 | 0.62 | 2-step | 750 |
| 3 | 6.30 | 2.8 | 0.37 | 0.22 | 2-step | 750 |
| 4 | 13.0 | 4.0 | 0.33 | 0.56 | 160° C. 10 min | 750 |
| 5 | 15.0 | 5.2 | 0.33 | 0.86 | 160° C. 10 min | 500 |
| 6 | 12.0 | 5.8 | 0.30 | 0.70 | 160° C. 10 min | 500 |
| 7 | 11.1 | 5.2 | 0.35 | 0.67 | 160° C. 10 min | 500 |

Number of coats for spray-on active layer: 5 light layers, and 2 heavy layers

Number of coats for the spray-on PEDOT:PSS layer:6-7 light layers, and 5 heavy layers

Number of coats for the spray-on Cs₂CO₃ layer: 1 light layer

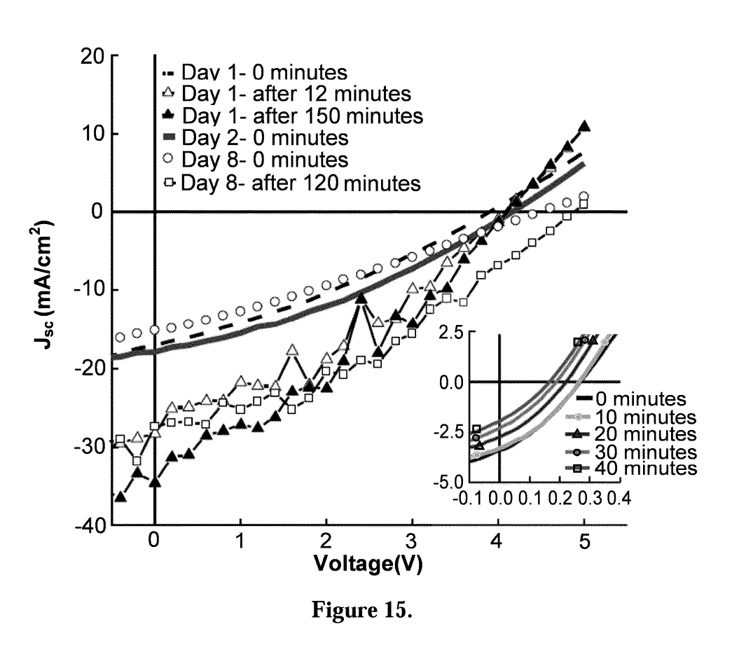

An interesting phenomenon was observed with the inverted organic photovoltaic cells, which is termed ‘photo annealing’, seen in FIG. 15. Under constant illumination from the solar simulator, a sudden change in I-V characteristics occurs after time, which is device dependent, ranging from 10 min to several hours. For example, the solar array shown in FIG. 15 required about 15 min to ‘photo anneal’, and reached a maximum PCE after 2.5 h under illumination. The most drastic change occurred in the I_{sc}, which more than doubled from 17 to 35 mA after 2.5 h. The change of V_{oc} was marginal, from 4.0 to 4.2 V, and the maximum PCE of the array was 1.80%. Table 3 listed the changes of other I-V characteristics.

TABLE 3
change of array I-V characteristics under solar illumination.

| Time | I_{sc} (mA) | V_{oc} (V) | FF | η (%) |
|---|---|---|---|---|
| Day 1 | | | | |
| −0 min | 17 | 4.0 | 0.30 | 0.68 |
| −12 min | 28 | 4.2 | 0.35 | 1.40 |
| −150 min | 35 | 4.2 | 0.37 | 1.80 |
| Day 2 | | | | |
| −0 min | 18 | 4.2 | 0.35 | 0.88 |
| Day 3 | | | | |
| −0 min | 15 | 4.4 | 0.29 | 0.64 |
| −120 min | 27 | 4.8 | 0.38 | 1.68 |

It was also noted that this sudden increase of I_{sc} was accompanied by a characteristic ‘wiggling’ on the I-V curve. Without being limited to any specific theory, several mechanisms may explain these observations. The first mechanism is due to optical interference causing re-distribution of light intensity within the active layer. The sealant epoxy was heated and softened, resulting in the change of the distance between encapsulating glass and the device, causing less optical loss. As a consequence, the short circuit current I_{sc} increases. This mechanism is supported by the inset of FIG. 15, which shows the fast decay of a spray-on test cell without encapsulation. Encapsulation also helped to minimize oxidization and slow down the decay of organic solar cell efficiency. The second mechanism is that photo annealing of active layer improved the device morphology and cured some of the weak points (burned out shorts), thereby improving I_{sc} and FF. It is also possible PCBM penetrated into the voids between polymer chains, causing better phase segregation (Geiser, et al., Poly(3-hexylthiophene)/C60 heterojunction solar cells: implication of morphology on performance and ambipolar charge collection, Sol. Eng. Sol. Cells 92 (2008) 464-473). As temperature drops down, the polymer chains go back to its original configuration, and the I-V curve is back to its original one, manifesting certain kind of thermal hysteresis. The third mechanism is due to the thermal activation of the previous deeply trapped carriers (i.e., polarons), which results in increased photocurrent at higher temperature (Graupner, et al., Shallow and deep traps in conjugated polymers of high intrachain order, Phys. Rev. B 54 (1996) 7610-7613; Nelson, Organic photovoltaic films, Curr. Opinion Solid State Mater. Sci. 6 (2002) 87-95). The wiggling of the I-V data indicate the non-uniformity of the film morphology, and the overall boost of device performance is the result of the free-up of previously trapped charges in the active layers. This observation is against the conventional picture of organic solar cell, which normally shows degradation under solar illumination (Dennler, et al., A new encapsulation solution for flexible organic solar cells, Thin Solid Films 511-512 (2006) 349-353). Surprisingly, this performance enhancement under illumination only happened with sprayed devices, not with a device made by spin coating. As such, solar cells prepared using the spray-on technique performs better under sunlight, which is obviously beneficial for solar energy application. The thermal annealing was important in improving device PCE. Moreover, the optimal annealing conditions are not the same with small single cell and large solar array consisting of 50 cells. Systematic study of optical, electronic and morphologic properties of the device revealed the influence of nanomorphology over device power conversion efficiency. Moreover, the photo annealing, i.e., more than 2-fold increase of solar cell PCE under solar irradiance and with hysteresis pattern, is in contrary to the normal understanding of organic solar cell degradation under sunlight. The fact that photo annealing was only observed with sprayed solar cell or arrays places an advantageous solution to for large scale, low-cost solution-based solar energy applications.

In the preceding specification, all documents, acts, or information disclosed do not constitute an admission that the document, act, or information of any combination thereof was publicly available, known to the public, part of the general knowledge in the art, or was known to be relevant to solve any problem at the time of priority.

The disclosures of all publications cited above are expressly incorporated herein by reference, each in its entirety, to the same extent as if each were incorporated by reference individually.

While there has been described and illustrated specific embodiments of an organic photovoltaic cell and methods of manufacturing the photovoltaic cell, it will be apparent to those skilled in the art that variations and modifications are possible without deviating from the broad spirit and principle of the present invention. It is also to be understood that the following claims are intended to cover all of the generic and specific features of the invention herein described, and all statements of the scope of the invention which, as a matter of language, might be said to fall therebetween.

What is claimed is:

1. An organic solar photovoltaic cell comprising:
a substrate having a first face and a second face, wherein the substrate is glass, plastic, or cloth;
a patterned ITO layer disposed on the first face of the glass, wherein the ITO layer is disposed as a plurality of contacts disposed in a first direction on the glass substrate;
a patterned interfacial buffer layer of Cs₂CO₃ disposed on the ITO layer;
an active layer of poly-3(hexylthiophene) and [6,6]-phenyl C61-butyric acid methylester disposed on the layer of Cs₂CO₃, wherein the active layer is about 200 nm thick to about 500 nm thick;
an anodic layer comprising poly(3,4)ethylenedioxythiophene:poly-styrenesulfonate and 5 vol. % of dimethylsulfoxide disposed on the active layer, wherein the anodic layer is about 100 nm to about 1 μm thick;
an encapsulating layer, wherein the encapsulating layer is glass, plastic, or cloth; and
a UV-cured epoxy encapsulant or silver paint disposed to form an airtight seal between the layers.

2. The organic solar photovoltaic cell of claim 1, wherein the glass is low alkaline earth boro-aluminosilicate glass.

3. The organic solar photovoltaic cell of claim 2, wherein the glass has a nominal sheet resistance of 4-10 Ohm/square.

4. The organic solar photovoltaic cell of claim 1, wherein the Cs₂CO₃ layer is between 5\acute{Å} to 15 \acute{Å} thick.

5. The organic solar photovoltaic cell of claim 1, wherein the active layer of has a layer thickness of about final layer thickness of about 200 to about 300 nm.

6. The organic solar photovoltaic cell of claim 5, wherein the thickness of the active layer is about 200 nm.

7. The organic solar photovoltaic cell of claim 1, wherein the thickness of the anodic layer is about 100 nm to about 600 nm.

8. The organic solar photovoltaic cell of claim 7, wherein the thickness of the anodic layer is about 100 nm.

9. The organic solar photovoltaic cell of claim 6, wherein the thickness of the active layer is 200 nm and the thickness of the anodic layer is 600 nm.

10. The organic solar photovoltaic cell of claim 1, further comprising a series of organic solar photovoltaic cells disposed into an array of 50 individual cells having active area of 60 mm².

11. The organic solar photovoltaic cell of claim 10, wherein the array further comprises 10 cells disposed in series in one row, and 5 rows in parallel connection.

12. A method for fabricating an organic inverted solar photovoltaic cell, comprising the steps of:
obtaining a substrate comprising a transparent piezoelectric material coated with indium tin oxide;
forming a cathode by spray coating a layer of cesium carbonate on top of the indium tin oxide coating;
forming an active layer by spray coating a layer of poly-3(hexylthiophene) and [6,6]-phenyl C61-butyric acid methylester disposed on the layer of Cs₂CO₃, wherein the active layer is about 200 nm thick to about 500 nm thick;
forming an anodic layer comprising poly(3,4)ethylenedioxythiophene:poly-styrenesulfonate doped with 5 vol. % of dimethylsulfoxide disposed on the active layer, wherein the anodic layer is about 100 nm to about 1 μm thick; and
encapsulating the organic inverted photovoltaic cell by applying a UV-cured epoxy encapsulant or silver paint to the edges of the cell.

13. The method of claim 12, further comprising the step of:
preparing the substrate for the cathode layer, comprising the steps of:
spin coating a positive photo resist at about 4500 rpm
soft baking the positive photo resist at 90° C. to pattern the indium tin oxide;
exposing the baked positive photo resist to UV irradiation at a constant intensity mode set to about 25 watts;
developing the exposed positive photo resist;
hard-baking the exposed positive photo resist at about 145° C.;
cleaning off excess photoresist using acetone and cotton; and
etching the substrate with a solution of 20% HCl-7% HNO₃ at 100° C.

14. The method of claim 13, further comprising cleaning the substrate by hand using acetone followed by isopropanol, followed by a UV-ozone clean.

15. The method of claim 12, further comprising preparing a layer of cesium by the steps of:
making a solution of 0.2% wt. (2 mg/mL) Cs₂CO₃ in 2-ethoxyethanol;
stirring the solution for one hour; and
placing the solution into a spray device containing N₂ propellant.

16. The method of claim 12, further comprising preparing the active layer by the steps of:
mixing a solutions of poly(3-hexylthiophene) in dichlorobenzene at 20 mg/mL for 24 hours at 60° C.;
mixing a solution of 6,6-phenyl C61 butyric acid methyl ester in dichlorobenzene at 20 mg/mL for 24 hours at 60° C.;
combining the solution of poly(3-hexylthiophene) and solution of 6,6-phenyl C61 butyric acid methyl ester at a ratio of 1:1 and stirring for 24 hours at 60° C.; and
placing the solution into a spray device containing N₂ propellant.

17. The method of claim 12, further comprising preparing anodic buffer layer by the steps of:
filtering a solution of poly(3,4)ethylenedioxythiophene and poly(styrenesulfonate) through a 0.45 μm filter;
mixing the solution of poly(3,4)ethylenedioxythiophene and poly(styrenesulfonate) with a solution of dimethylsulfoxide to form a final concentration of dimethylsulfoxide of 5 vol %;
stirring the solution of poly(3,4)ethylenedioxythiophene-poly(styrenesulfonate)-dimethylsulfoxide at room temperature;
sonifying the solution of poly(3,4)ethylenedioxythiophene-poly(styrenesulfonate)-dimethylsulfoxide for 1 hour; and
placing the solution into a spray device containing N₂ propellant.

18. The method of claim 17, further comprising:
applying a mask to the active layer of the organic inverted solar photovoltaic cell;
placing the organic inverted solar photovoltaic cell and mask on a hotplate at 90° C. spray coated the solution of poly(3,4)ethylenedioxythiophene-poly(styrenesulfonate)-dimethylsulfoxide onto the active layer;
removing the organic inverted solar photovoltaic cell and mask from the hotplate; and
removing the mask from the organic inverted solar photovoltaic cell.

19. The method of claim 12, further comprising annealing the layers together after the anodic layer is applied, comprising the steps of:
subjecting the organic inverted solar photovoltaic cell to a vacuum of 10⁻⁶ Torr; and
annealing the organic inverted solar photovoltaic cell at 120° C.

20. The method of claim 8, further comprising the steps of:
subjecting the substrate to a high vacuum (10⁻⁶) Torr for one (1) hour for a second time; and
annealing the organic inverted solar photovoltaic cell at 160° C.

21. The method of claim 12, wherein the substrate is a low alkaline earth boro-aluminosilicate glass substrate.

22. The method of claim 21, wherein the step of encapsulating the organic inverted photovoltaic cell further comprises the steps of:
encapsulating the glass substrate using silver paint and applying the silver paint to at least one contact on the glass substrate;
allowing the silver paint to dry;
notching an encapsulation glass;
cleaning the encapsulation glass using acetone and isopropanol;
cleaning the glass substrate using UV-ozone;
placing the encapsulation glass into a glovebox with a UV-cure epoxy;
applying the UV-cure epoxy to the edge of the encapsulation glass;
inverting the substrate and placing it onto the encapsulation glass; and
exposing the substrate to UV-ozone.
